(19) United States
(12) Patent Application Publication
(10) Pub. No.: US 2015/0155216 A1
(43) Pub. Date: Jun. 4, 2015

(54) SEMICONDUCTOR CHIP AND METHOD OF FORMING THE SAME

(71) Applicant: Samsung Electronics Co., Ltd., Suwon-si (KR)

(72) Inventors: JONGKOOK KIM, Hwaseong-si (KR); BYOUNG WOOK JANG, Hwaseong-si (KR)

(21) Appl. No.: 14/491,957

(22) Filed: Sep. 19, 2014

(30) Foreign Application Priority Data
Dec. 3, 2013 (KR) 10-2013-0149210

(51) Int. Cl. H01L 23/31; H01L 21/02; H01L 21/3105; H01L 23/00

(52) U.S. Cl. CPC H01L 23/3171; H01L 23/562; H01L 24/06; H01L 24/14; H01L 21/02118; H01L 21/31058; H01L 21/0217; H01L 24/11; H01L 2924/14; H01L 2224/0401; H01L 2224/05026; H01L 2224/13022; H01L 2224/13017; H01L 2224/13014; H01L 2924/07025

(57) ABSTRACT

A semiconductor chip comprising: a substrate; a plurality of pads disposed on the substrate; and a plurality of passivation patterns laterally separated from each other on the substrate, each of the passivation patterns including a plurality of openings, the openings exposing at least one pad of the pads, and the passivation patterns having a thermal expansion coefficient different from a thermal expansion coefficient of the substrate.

### CROSS-REFERENCE TO RELATED APPLICATION

This U.S. non-provisional patent application claims priority under 35 U.S.C. §119 to Korean Patent Application No. 10-2013-0149210, filed on Dec. 3, 2013, in the Korean Intellectual Property Office, the disclosure of which is hereby incorporated by reference in its entirety.

### BACKGROUND

Embodiments relate to a semiconductor and, more particularly, to semiconductor chips and methods of forming the same.

Electronic devices may include semiconductor integrated circuits integrated on semiconductor chips. As the semiconductor integrated circuits have become highly integrated, sizes of the semiconductor chips have become more and more reduced. Flip chip bonding techniques using bumps are widely used to mount the semiconductor chips on package substrates. In addition, thicknesses of the semiconductor chips are being reduced with the miniaturization trend of semiconductor products. However, thin semiconductor chips may be warped, so that performance of semiconductor integrated circuits on such thin semiconductor chips may deteriorate.

### SUMMARY

An embodiment includes a semiconductor chip comprising: a substrate; a plurality of pads disposed on the substrate; and a plurality of passivation patterns laterally separated from each other on the substrate, each of the passivation patterns including a plurality of openings, the openings exposing at least one pad of the pads, and the passivation patterns having a thermal expansion coefficient different from a thermal expansion coefficient of the substrate.

Another embodiment includes a system, comprising: a plurality of semiconductor chips, at least one of the semiconductor chips comprising: a substrate; and a passivation layer formed on the substrate and including a plurality of grooves separating the passivation layer into a plurality of passivation patterns, each of the passivation patterns having a thermal expansion coefficient different from a thermal expansion coefficient of the substrate; and a plurality of pads exposed through openings in the passivation layer.

Another embodiment includes a method of forming a semiconductor chip, the method comprising: providing a substrate including pads; forming a passivation layer on the substrate, the passivation layer having a thermal expansion coefficient different from that of the substrate; patterning the passivation layer to form a plurality of passivation patterns separated from each other, each of the passivation patterns including a plurality of openings, each opening exposing a corresponding one of the pads; forming under bump patterns in the openings; and forming bumps on the under bump patterns.

### BRIEF DESCRIPTION OF THE DRAWINGS

Embodiments will become more apparent in view of the attached drawings and accompanying detailed description.

FIG. 1 is a plan view illustrating a semiconductor chip according to some embodiments;

FIG. 2 is a cross-sectional view taken along a line I-I′ of FIG. 1;

FIGS. 3 to 7 are cross-sectional views and plan views illustrating a method of forming a semiconductor chip according to some embodiments;

FIG. 8 is a diagram illustrating a package module including a semiconductor chip according to some embodiments;

FIG. 9 is a schematic block diagram illustrating an electronic system including a semiconductor chip according to some embodiments; and

FIG. 10 is a schematic block diagram illustrating a memory card including a semiconductor chip according to some embodiments.

### DETAILED DESCRIPTION OF THE EMBODIMENTS

Embodiments will now be described more fully hereinafter with reference to the accompanying drawings. The advantages and features of the embodiments will be apparent from the following embodiments that will be described in more detail with reference to the accompanying drawings. It should be noted, however, that embodiments are not limited to the particular embodiments, and may take various other forms. Accordingly, these embodiments are provided only to disclose the concepts to those skilled in the art. In the drawings, embodiments are not limited to the specific examples provided herein and particular portions may be exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, embodiments may be described with sectional views as ideal views. Accordingly, shapes of the particular views may be different according to manufacturing techniques and/or allowable errors. Therefore, embodiments are not limited to the specific shape illustrated in the exemplary views, but may include other shapes that may be created according to manufacturing processes. Areas exemplified in the drawings have general properties, are used to illustrate specific shapes of elements, and should not be construed as limited to the scope of particular embodiments unless specifically expressed.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Elements explained and illustrated herein may include their complementary counterparts. The same reference numerals or the same reference designators denote the same elements throughout the specification.

Moreover, particular embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

Hereinafter, semiconductor chips and methods of forming the same according to various embodiments will be described with reference to the drawings.

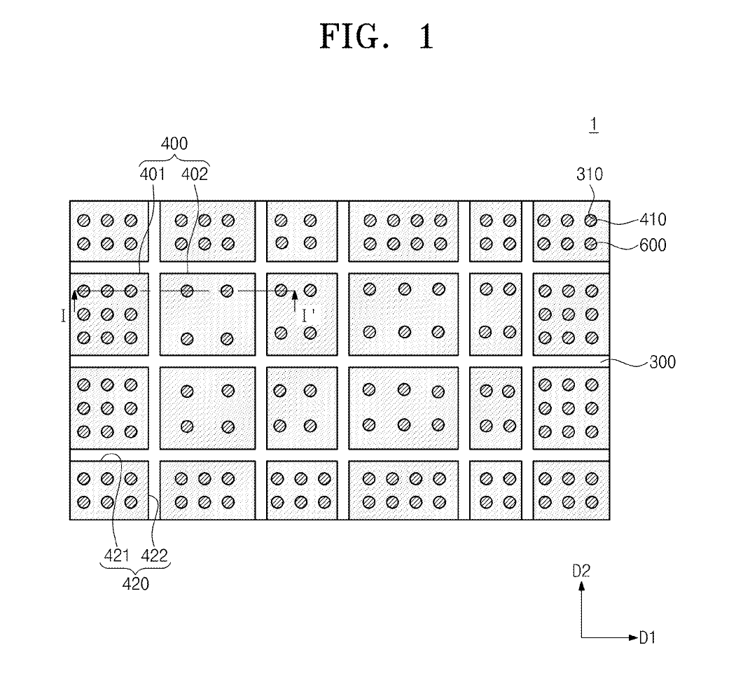

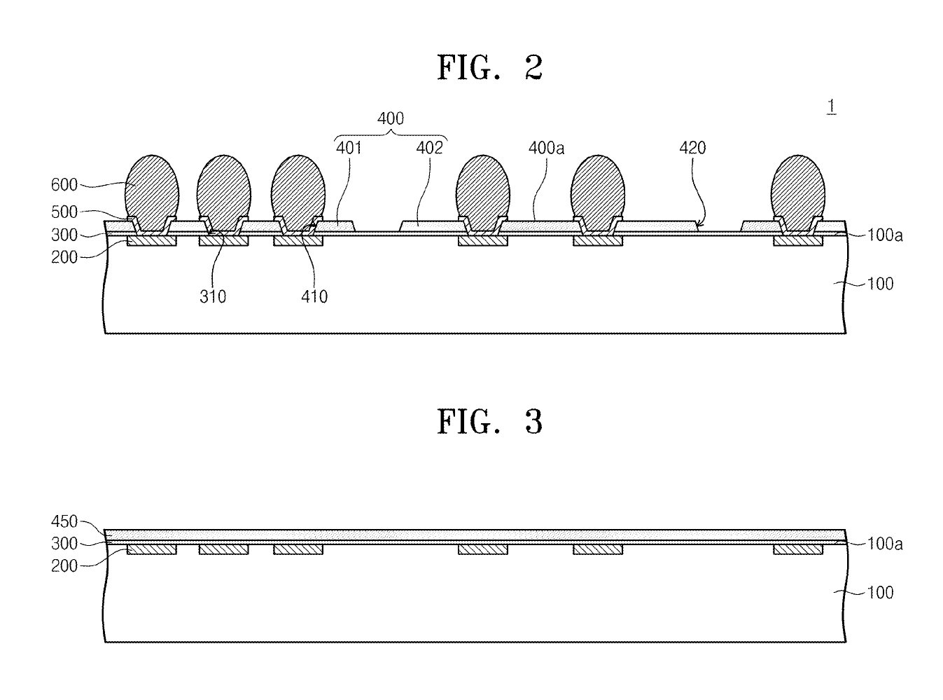

FIG. 1 is a plan view illustrating a semiconductor chip according to some embodiments. FIG. 2 is a cross-sectional view taken along a line I-I′ of FIG. 1.

Referring to FIGS. 1 and 2, a semiconductor chip 1 may include pads 200, an insulating layer 300, passivation patterns 400, under bump patterns 500, and bumps 600 that are provided at a surface 100a of a substrate 100.

The substrate 100 may be a silicon substrate, or other substrate in which an integrated circuit may be formed. The substrate 100 may have a thermal expansion coefficient in a range of about 1 ppm/° C. to about 5 ppm/° C. For example, the substrate 100 may have the thermal expansion coefficient of about 2.6 ppm/° C. The substrate 100 may include an integrated circuit, for example, a memory circuit, a logic circuit, or a combination thereof.

The insulating layer 300 may substantially cover the substrate 100. The insulating layer 300 may have holes 310 that expose the pads 200, respectively. The pads 200 may include a conductive material, for example, aluminum, copper, or the like. The insulating layer 300 may include silicon nitride, silicon oxide, silicon oxynitride, other similar materials, or combinations of such materials. In some embodiments, the insulating layer 300 may include silicon nitride. The insulating layer 300 may have a thermal expansion coefficient in a range of about 1 ppm/° C. to about 5 ppm/° C. The insulating layer 300 may protect the substrate 100.

The passivation patterns 400 may be disposed on the insulating layer 300. Each of the passivation patterns 400 may include multiple openings 410. The openings 410 may overlap with the holes 310 of the insulating layer 300, respectively, when viewed from a plan view. The openings 410 may expose the pads 200, respectively. The passivation patterns 400 may include an organic material. For example, the passivation patterns 400 may include a photosensitive polyimide. The passivation patterns 400 may prevent damage (e.g., a crack) of the substrate 100.

Grooves 420 may be defined between the passivation patterns 400. The grooves 420 may include first grooves 421 extending in a first direction D1 and second grooves 422 extending in a second direction D2. The second grooves 422 may intersect the first grooves 421. The first and second directions D1 and D2 may be parallel to the one surface 100a of the substrate 100. The grooves 420 may expose the insulating layer 300. Alternatively, the grooves 420 may expose the substrate 100. The passivation patterns 400 may be completely separated from each other by the grooves 420. The passivation patterns 400 may be laterally spaced apart from each other. The passivation patterns 400 may have a thermal expansion coefficient different from those of the substrate 100 and the insulating layer 300. The thermal expansion coefficient of the passivation patterns 400 may be equal to or greater than about 10 times the thermal expansion coefficient of the substrate 100. In particular, the thermal expansion coefficient of the passivation patterns 400 may be in a range of about 10 times to about 10,000 times the thermal expansion coefficient of the substrate 100. For example, the passivation patterns 400 may have the thermal expansion coefficient of about 35 ppm/° C. A stress may be applied between the substrate 100 and the passivation patterns 400 by a difference between the thermal expansion coefficients of the substrate 100 and the passivation patterns 400. As a thickness of the substrate 100 is reduced, the stress applied to the semiconductor chip 1 may increase. However, according to some embodiments, since the passivation patterns 400 are separated from each other, the stress applied between the substrate 100 and the passivation patterns 400 may be relieved. Thus, warpage of the semiconductor chip 1 may be minimized or prevented.

The grooves 420 may not overlap with the bumps 600. Positions or arrangement of the grooves 420 may be determined depending on intervals between the bumps 600. For example, intervals between the first grooves 421 may not be equal to each other. Additionally, intervals between the second grooves 422 may not be equal to each other. Thus, shapes of the passivation patterns 400 separated by the grooves 420 may not be the same as each other. For example, the passivation patterns 400 may include a first passivation pattern 401 and a second passivation pattern 402. A density of the openings 410 of the first passivation pattern 401 may be different from a density of the openings of the second passivation pattern 402. A planar area of the first passivation pattern 401 may be different from a planar area of the second passivation pattern 402.

Although the grooves 420 have been illustrated as extending in perpendicular directions, in other embodiments, the grooves 420 may extend in other non-perpendicular directions. Moreover, although the grooves 420 are illustrated as extending in substantially straight directions, the grooves 420 may follow non-linear paths. Furthermore, as the grooves 420 may take a variety of different forms, the passivation patterns 400 may take corresponding different forms.

Each of the under bump patterns 500 may be provided in each of the holes 310 and each of the openings 410 overlapping with each other at the one surface 100a of the substrate 100. The under bump pattern 500 may be in contact with the pad 200 corresponding to a bottom surface of the hole 310. Additionally, the under bump pattern 500 may extend along sidewalls of the hole 310 and the opening 410 onto a top surface 400a of the passivation pattern 400 adjacent to the opening 410. The under bump patterns 500 may be spaced apart from each other. The under bump patterns 500 may include a conductive material. For example, the under bump patterns 500 may include at least one of titanium, nickel, copper, or similar materials. The under bump patterns 500 may be formed of a single layer or a multi-layer.

The bumps 600 may be provided on the under bump patterns 500 in the openings 410, respectively. The number and/or arrangement of the bumps 600 may be various. For example, the bumps 600 may be non-uniformly arranged when viewed from a plan view. In some embodiments, an arrangement state of the bumps 600 in a center region of the substrate 100 may be different from an arrangement state of the bumps 600 in an edge region of the substrate 100, as illustrated in FIG. 1. In other embodiments, the bumps 600 may be uniformly arranged on the one surface 100a of the substrate 100. The bumps 600 may include a conductive material. For example, the bumps 600 may include at least one of copper, tin, or silver. Each of the bumps 600 may be electrically connected to each of the pads 200 through each of the under bump patterns 500 in each of the openings 410. An external electronic device (not shown) may be electrically connected to the semiconductor chip 1 through the bumps 600.

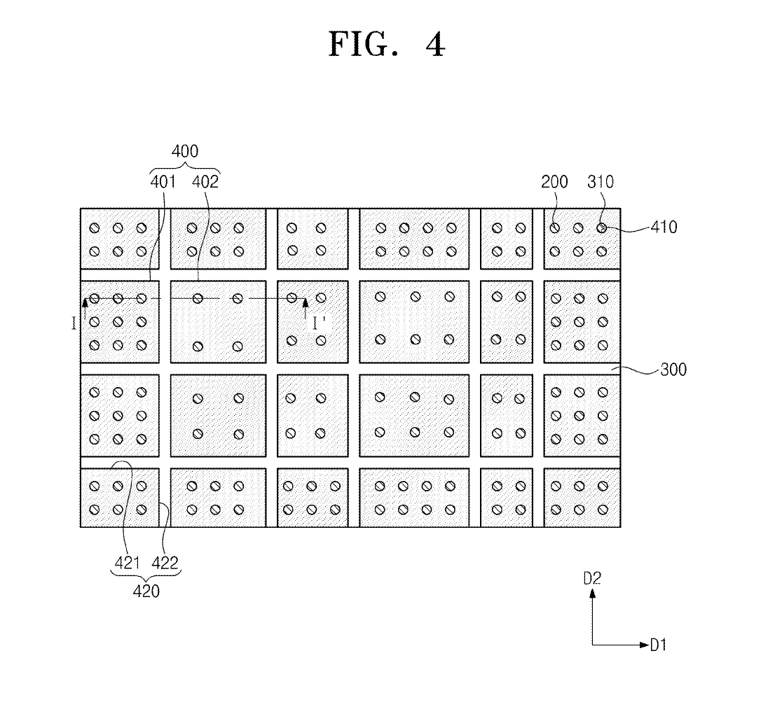

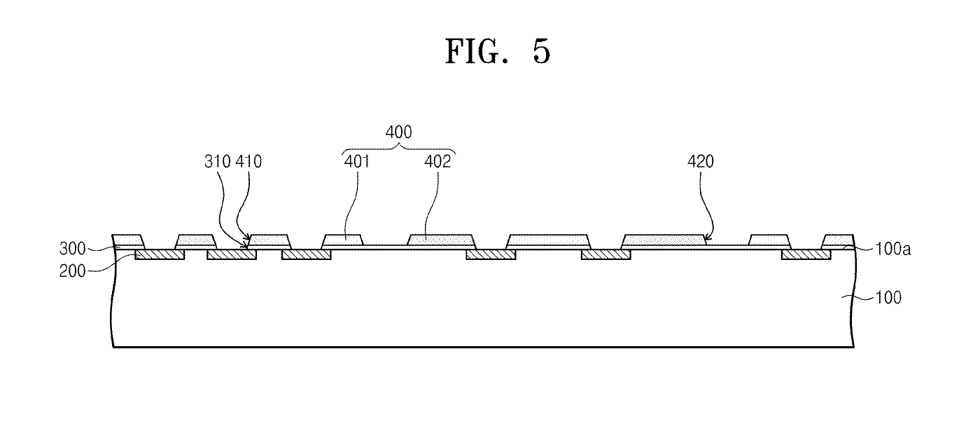

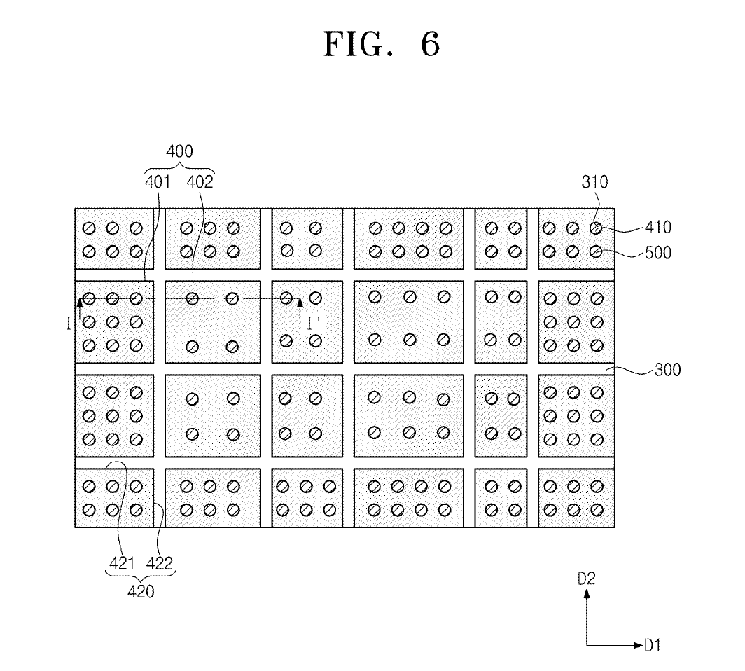

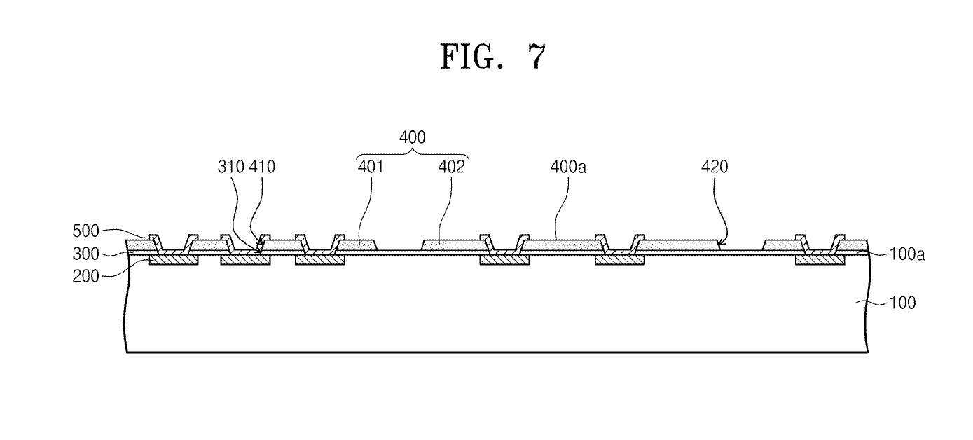

FIGS. 3 to 7 are cross-sectional views and plan views illustrating a method of forming a semiconductor chip according to some embodiments. FIG. 3 is a cross-sectional view, FIGS. 4 and 6 are plan views, and FIGS. 5 and 7 are cross-sectional views taken along lines I-I′ of FIGS. 4 and 6, respectively. Hereinafter, the same descriptions as described with reference to FIGS. 1 and 2 will be omitted or mentioned briefly.

Referring to FIG. 3, pads 200, an insulating layer 300, and a passivation layer 450 may be formed at a surface 100a of the substrate 100. In more detail, the substrate 100 in which the pads 200 are formed may be prepared. Positions of the pads 200 may be determined by an integrated circuit (not shown) formed on the substrate 100. The insulating layer 300 may be formed on the surface 100a of the substrate 100 to cover the pads 200. The insulating layer 300 may include at least one of silicon oxide, silicon oxynitride, silicon nitride, or the like as described above. The passivation layer 450 may be formed on the insulating layer 300. The passivation layer 450 may include an organic material, e.g., a photosensitive polyimide, or the like. A thermal expansion coefficient of the passivation layer 450 may be different from those of one or more of the substrate 100 and the insulating layer 300. For example, the thermal expansion coefficient of the passivation layer 450 may be equal to or greater than about 10 times the thermal expansion coefficient of the substrate 100.

Referring to FIGS. 4 and 5, the passivation layer 450 may be patterned to form multiple passivation patterns 400 completely separated from each other. The passivation patterns 400 may be laterally spaced apart from each other by grooves 420. The grooves 420 may expose the insulating layer 300. The grooves 420 may be formed to extend between the pads 200 when viewed from a plan view. Positions and/or an arrangement state of the grooves 420 may be determined depending on the positions and the arrangement state of the pads 200. For example, the grooves 420 may be formed in places where a density of the pads 200 is changed. A density of the pads 200 of each passivation pattern 400 provided at a side of each groove 420 may be different from a density of the pads 200 of each passivation pattern 400 provided at another side of each groove 420. For example, a density of openings 410 disposed in a first passivation pattern 401 may be different from a density of openings 410 disposed in a second passivation pattern 402. A planar area of the first passivation pattern 401 may be different from a planar area of the second passivation pattern 402. Shapes of the passivation patterns 400 separated from each other by the grooves 420 may not be the same as each other. The grooves 420 may include first grooves 421 and second grooves 422 intersecting the first grooves 421. Intervals between the first grooves 421 may not be equal to each other. Intervals between the second grooves 422 may not be equal to each other. The intervals between the first grooves 421 and the intervals between the second grooves 422 may be in a range of about 500 μm to about 5 mm. Multiple openings 410 may be formed in each of the passivation patterns 400. The grooves 420 may be formed simultaneously with the openings 410. In some embodiments, the grooves 420 and the openings 410 may be formed by a photolithography process and an etching process. Since the grooves 420 and the openings 410 are formed at the same time, an additional process for separating the passivation patterns 400 may not be required. As a result, forming processes of the semiconductor chip 1 may be simplified. The insulating layer 300 may be patterned to form holes 310. The holes 310 may overlap with the openings 410, respectively. Each hole 310 and each opening 410 overlapping with each other may expose each pad 200. The holes 310 may be formed by a photolithography process and an etching process. The insulating layer 300 exposed by the grooves 420 may not be etched.

In some embodiments, a spacing of the grooves 420 may be selected based on the difference between the thermal expansion coefficient of the passivation layer 450 and the thermal expansion coefficient of the substrate 100. For example, a threshold distance may be determined based on the difference between the thermal expansion coefficient of the passivation layer 450 and the thermal expansion coefficient of the substrate 100. Accordingly, although the grooves 420 may be separated by a variety of different distances, in some embodiments, the separation of any two grooves 420 may be less than the threshold distance.

Referring to FIGS. 6 and 7, an under bump pattern 500 may be formed in each hole 310 and each opening 410 overlapping with each other. For example, a mask layer (not shown) exposing the openings 410 may be formed on the surface 100a of the substrate 100, and the under bump patterns 500 may be then formed in the openings 410 by an electroplating process using the mask layer. Each under bump pattern 500 may cover a bottom surface of the opening 410 (i.e., the a bottom surface of the hole 310) so as to be in contact with each pad 200. The method of forming the under bump patterns 500 is not limited to this method. In other words, the under bump patterns 500 may be formed by various different methods. The under bump pattern 500 may extend along sidewalls of the hole 310 and the opening 410 onto a top surface 400a of the passivation pattern 400 adjacent to the opening 410. The under bump patterns 500 may be electrically insulated from each other. The under bump patterns 500 may include a conductive material, e.g., copper, nickel, titanium, or the like.

Referring again to FIGS. 1 and 2, bumps 600 may be formed on the under bump patterns 500 disposed in the openings 410, respectively. The bumps 600 may conductive material, e.g., copper, tin, silver, or the like. Positions of the bumps 600 may not be limited by the grooves 420. That is, although the bumps 600 may be formed after the grooves 420, in some embodiments, the position of the bumps 600 may define and/or limit the positions of the grooves 420.

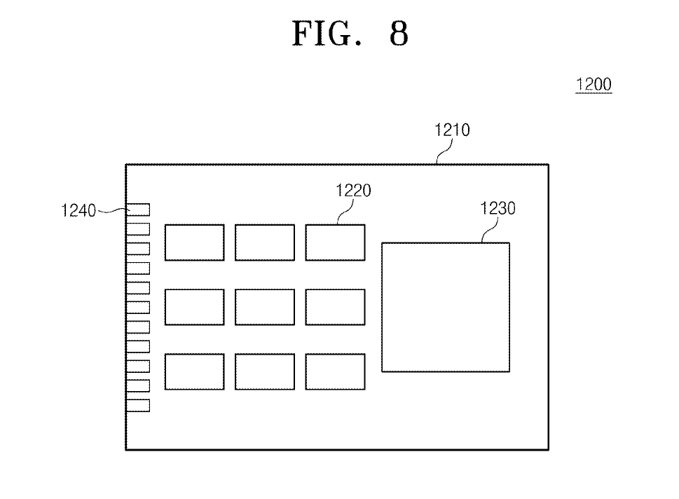

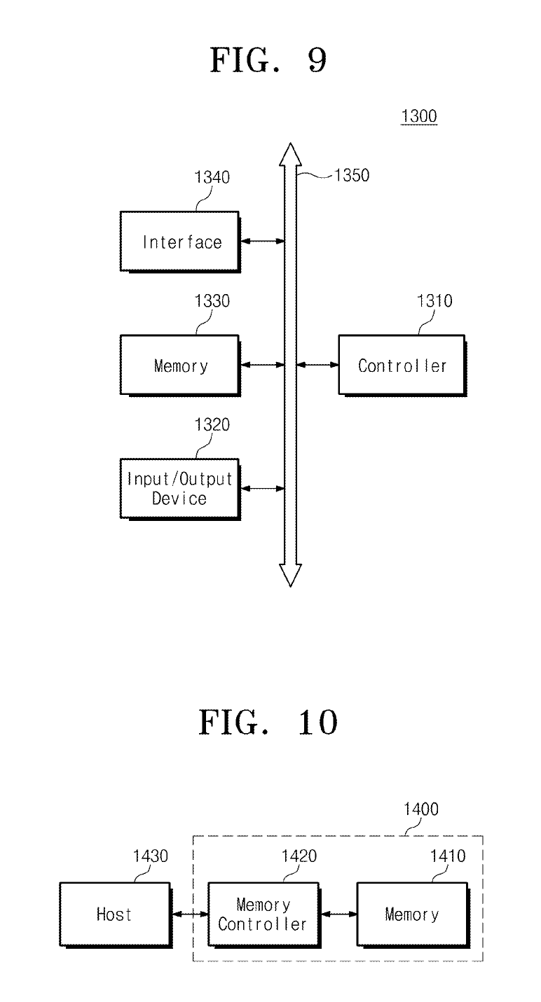

FIG. 8 is a diagram illustrating a package module including a semiconductor chip according to some embodiments. FIG. 9 is a schematic block diagram illustrating an electronic system including a semiconductor chip according to some embodiments. FIG. 10 is a schematic block diagram illustrating a memory card including a semiconductor chip according to some embodiments.

Referring to FIG. 8, a package module 1200 may include first semiconductor integrated circuit chips 1220 and a second semiconductor integrated circuit chip 1230. One or more of the first semiconductor integrated circuit chips 1220 and the second semiconductor integrated circuit chip 1230 may be packaged using a quad flat package (QFP) technique. One or more of the semiconductor integrated circuit chips 1220 and 1230 may include a semiconductor chip 1 according to some embodiments. The package module 1200 may be connected to an external electronic device through external connection terminals 1240 provided on a side of a board 1210.

Referring to FIG. 9, an electronic system 1300 may include a controller 1310, an input/output (I/O) device 1320, and a memory 1330. The controller 1310, the I/O device 1320, and the memory 1330 may be configured to communicate with each other through a data bus 1350. The data bus 1350 may correspond to a path through which electrical signals are transmitted. For example, the controller 1310 may include at least one of a microprocessor, a digital signal processor, a microcontroller, and other logic devices having a similar function to any one thereof. One or more of the controller 1310, the I/O device 1320, and the memory device 1330 may include a semiconductor chip 1 according to one or more of the aforementioned embodiments. The I/O device 1320 may include at least one of a keypad, a keyboard, or a display unit. The memory device 1330 may include a device configured to store data. The memory device 1330 may be configured to store data and/or commands to be executed by the controller 1310. The memory device 1330 may include a volatile memory device and/or a non-volatile memory device. In some embodiments, the memory device 1330 may include a flash memory device. For example, the flash memory device including a semiconductor chip according to an embodiment may be installed in an information processing system such as a mobile device or a desktop computer. The flash memory device may be in the form of a solid state disk (SSD). In this case, the electronic system 1300 may stably store large amounts of data in the memory device 1330. The electronic system 1300 may further include an interface 1340 configured to transmit electrical data to a communication network or receive electrical data from a communication network. The interface 1340 may be a wired or wireless interface. For example, the interface 1340 may include an antenna for wireless communication or a transceiver for wired communication. Although not shown in the drawings, the electronic system 1300 may further include an application chipset and/or a camera image processor (CIS).

The electronic system 1300 may be realized as a mobile system, a personal computer, an industrial computer, or a multi-functional logic system. For example, the mobile system may be one of a personal digital assistant (PDA), a portable computer, a web tablet, a wireless phone, a mobile phone, a laptop computer, a digital music player, a memory card, or an information transmitting/receiving system. If the electronic system 1300 is an apparatus capable of performing a wireless communication, the electronic system 1300 may be used in a communication interface protocol such as a third generation communication system (e.g., CDMA, GSM, NADC, E-TDMA, WCDMA, CDMA2000), or other communication system.

Referring to FIG. 10, a memory card 1400 may include a non-volatile memory device 1410 and a memory controller 1420. The non-volatile memory device 1410 and the memory controller 1420 may be configured to store data or read stored data. The memory controller 1420 may be configured to read data from/store data into the non-volatile memory device 1410 in response to read/write request of a host 1430. At least one of the memory device 1410 and the memory controller 1420 may include the semiconductor chip 1 according to one or more of the aforementioned embodiments.

In some embodiments, the passivation patterns may be separated from each other by the grooves. The passivation patterns may have a thermal expansion coefficient different from that of the substrate. The stress applied between the substrate and the passivation patterns may be reduced or relieved by the passivation patterns being separated from each other. Thus, the warpage phenomenon of the semiconductor chip may be provided.

In addition, the grooves may be formed simultaneously with the openings, and the positions and the arrangement state of the bumps may not be limited by the grooves. Thus, the passivation patterns may be easily formed.

Embodiments may include semiconductor chips having increased reliability and methods of forming the same.

Embodiments may include semiconductor chips capable of improving resistance to warpage and methods of forming the same.

In some embodiments, the semiconductor chip may include: a substrate; pads provided on the substrate; a plurality of passivation patterns laterally separated from each other on the substrate, each of the passivation patterns including a plurality of openings, the openings exposing the pads, respectively, and the passivation patterns having a thermal expansion coefficient different from that of the substrate; under bump patterns provided in the openings, respectively; and bumps provided on the under bump patterns, respectively.

In some embodiments, the passivation patterns may include a photosensitive polyimide.

In some embodiments, the thermal expansion coefficient of the passivation patterns may be equal to or greater than 10 times the thermal expansion coefficient of the substrate.

In some embodiments, the semiconductor chip may further include: an insulating layer disposed on the substrate. The insulating layer may include holes respectively exposing the pads, and the passivation patterns may be disposed on the insulating layer. The insulating layer may have a thermal expansion coefficient in a range of about 1 ppm/° C. to about 5 ppm/° C.

In some embodiments, the insulating layer may include silicon nitride.

In some embodiments, grooves may be defined between the passivation patterns. The grooves may expose the insulating layer.

In some embodiments, the passivation patterns may include: a first passivation pattern; and a second passivation pattern. A density of the openings of the first passivation pattern may be different from a density of the openings of the second passivation pattern.

In some embodiments, the passivation patterns may include: a first passivation pattern; and a second passivation pattern, and the first passivation pattern may have a planar area different from that of the second passivation pattern.

In some embodiments, each of the under bump patterns may extend along a sidewall of each of the openings onto a top surface of each of the passivation patterns adjacent to each of the openings.

In some embodiments, the method may include: providing a substrate including pads; forming a passivation layer on the substrate, the passivation layer having a thermal expansion coefficient different from that of the substrate; patterning the passivation layer to form a plurality of passivation patterns separated from each other, each of the passivation patterns including a plurality of openings, and the openings exposing the pads, respectively; forming under bump patterns in the openings, respectively; and forming bumps on the under bump patterns, respectively.

In some embodiments, the passivation patterns may be separated from each other by grooves, and the openings may be formed simultaneously with the grooves.

In some embodiments, the passivation patterns may include a photosensitive polyimide.

In some embodiments, the passivation patterns may include: a first passivation pattern; and a second passivation pattern, and a density of the openings of the first passivation pattern may be different from a density of the openings of the second passivation pattern.

In some embodiments, the method may further include: forming an insulating layer on the substrate. The insulating layer may include holes respectively exposing the pads, and the passivation patterns may be formed on the insulating layer. The insulating layer may have a thermal expansion coefficient in a range of about 1 ppm/° C. to about 5 ppm/° C.

In some embodiments, the insulating layer may include silicon nitride.

While embodiments have been described with reference to particular embodiments, it will be apparent to those skilled in the art that various changes and modifications may be made without departing from the spirit and scope of the following claims. Therefore, it should be understood that the above embodiments are not limiting, but illustrative. Thus, the scope of the following claims and their equivalents, and shall not be restricted or limited by the foregoing description.

What is claimed is:

1. A semiconductor chip, comprising:
a substrate;
a plurality of pads disposed on the substrate; and
a plurality of passivation patterns laterally separated from each other on the substrate, each of the passivation patterns including a plurality of openings, the openings exposing at least one pad of the pads, and the passivation patterns having a thermal expansion coefficient different from a thermal expansion coefficient of the substrate.

2. The semiconductor chip of claim 1, wherein the passivation patterns include a photosensitive polyimide.

3. The semiconductor chip of claim 1, wherein the thermal expansion coefficient of the passivation patterns is equal to or greater than about 10 times the thermal expansion coefficient of the substrate.

4. The semiconductor chip of claim 1, further comprising:
an insulating layer disposed on the substrate;
wherein:
the insulating layer includes holes respectively exposing the pads;
the passivation patterns are disposed on the insulating layer; and
the insulating layer has a thermal expansion coefficient in a range of about 1 ppm/° C. to about 5 ppm/° C.

5. The semiconductor chip of claim 4, wherein the insulating layer includes silicon nitride.

6. The semiconductor chip of claim 4, wherein:
the passivation patterns are separated by grooves; and
the grooves expose the insulating layer.

7. The semiconductor chip of claim 1, wherein:
the passivation patterns comprise a first passivation pattern and a second passivation pattern; and
a density of the openings of the first passivation pattern is different from a density of the openings of the second passivation pattern.

8. The semiconductor chip of claim 1, wherein:
the passivation patterns comprise a first passivation pattern and a second passivation pattern; and
the first passivation pattern has a planar area different from that of the second passivation pattern.

9. The semiconductor chip of claim 1, further comprising a plurality of under bump patterns disposed in the openings.

10. The semiconductor chip of claim 9, further comprising a plurality of bumps disposed on the under bump patterns.

11. The semiconductor chip of claim 9, wherein each of the under bump patterns extends along a sidewall of the corresponding opening onto a top surface of the passivation pattern adjacent to the corresponding opening.

12. A method of forming a semiconductor chip, the method comprising:
providing a substrate including pads;
forming a passivation layer on the substrate, the passivation layer having a thermal expansion coefficient different from that of the substrate;
patterning the passivation layer to form a plurality of passivation patterns separated from each other, each of the passivation patterns including a plurality of openings, each opening exposing a corresponding one of the pads;
forming under bump patterns in the openings; and
forming bumps on the under bump patterns.

13. The method of claim 12, wherein:
patterning the passivation layer comprises forming grooves separating the passivation patterns from each other; and
the grooves and the openings are formed simultaneously.

14. The method of claim 12, wherein the passivation patterns include a photosensitive polyimide.

15. The method of claim 12, wherein:
patterning the passivation layer comprises forming a first passivation pattern and a second passivation pattern; and
a density of the openings of the first passivation pattern is different from a density of the openings of the second passivation pattern.

16. The method of claim 12, further comprising:
forming an insulating layer on the substrate, the insulating layer including holes exposing the pads and having a thermal expansion coefficient in a range of about 1 ppm/° C. to about 5 ppm/° C.;
wherein forming the passivation layer comprises forming the passivation layer on the insulating layer.

17. The method of claim 16, wherein the insulating layer includes silicon nitride.

18. A system, comprising:
a plurality of semiconductor chips, at least one of the semiconductor chips comprising:
a substrate; and
a passivation layer formed on the substrate and including a plurality of grooves separating the passivation layer into a plurality of passivation patterns, each of the passivation patterns having a thermal expansion coefficient different from a thermal expansion coefficient of the substrate; and
a plurality of pads exposed through openings in the passivation layer.

19. The system of claim 18, wherein for the at least one of the semiconductor chips, a separation of the grooves is less than a threshold based on a difference between the thermal expansion coefficient different from the thermal expansion coefficient of the substrate.

20. The system of claim 18, wherein for the at least one of the semiconductor chips, the grooves extend in at least two directions.
